(19) United States
(12) Patent Application Publication
(10) Pub. No.: US 2024/0268018 A1
(43) Pub. Date: Aug. 8, 2024

(54) INSULATING SUBSTRATE, ELECTRICAL WIRING SUBSTRATE, THERMAL PRINT HEAD AND MANUFACTURING METHODS THEREOF

(71) Applicant: ROHM CO., LTD., KYOTO (JP)

(72) Inventor: GORO NAKATANI, KYOTO (JP)

(21) Appl. No.: 18/410,805

(22) Filed: Jan. 11, 2024

(30) Foreign Application Priority Data
Feb. 6, 2023 (JP) 2023-015988

(51) Int. Cl. H05K 1/03; B41J 2/335; H01L 21/48; H01L 23/00; H01L 23/15; H01L 23/498; H05K 3/06; H05K 3/22

(52) U.S. Cl. CPC H05K 1/0306; B41J 2/3352; B41J 2/33535; B41J 2/3355; B41J 2/33575; B41J 2/3359; H01L 21/4867; H01L 23/15; H01L 23/49894; H05K 3/22; H01L 23/49838; H01L 24/48; H01L 2224/48091; H01L 2224/48227; H01L 2924/1426; H01L 2924/15787; H05K 3/064; H05K 2203/1131; H05K 2203/1461

(57) ABSTRACT

The present disclosure provides an insulating substrate. The insulating substrate includes a ceramic substrate having a main surface and a planarization layer covering the main surface. The planarization layer is a ceramic layer.

### TECHNICAL FIELD

The present disclosure relates to an insulating substrate, an electrical wiring substrate, a thermal print head, and manufacturing methods thereof.

### BACKGROUND

The Japan Patent Publication No. 2020-163654 (patent publication 1) discloses a thermal print head including an insulating substrate, a heat glaze, a chip bonding glaze, an intermediate glass layer, a heat resistor and an electrode layer. The insulating substrate includes a main surface. The intermediate glass layer covers a part located between the heat glaze and the chip bonding glaze on the main surface of the insulating substrate. The intermediate glass layer is contact with the heat glaze and the chip bonding glaze. A softening point of the intermediate glass layer is lower than a softening point of the heat glaze and a softening point of the chip bonding glaze. The electrode layer is arranged on the heat glaze, the intermediate glass layer and the chip bonding glaze, and is connected to the heat resistor.

### PRIOR ART DOCUMENT

### Patent publication

[Patent document 1] Japan Patent Publication No. 2020-163654

### BRIEF DESCRIPTION OF THE DRAWINGS

FIG. 1 is a schematic enlarged partial plan view of an electrical wiring substrate according to a first embodiment.

FIG. 2 is a schematic enlarged partial cross-sectional view of the electrical wiring substrate along the section line II-II in FIG. 1 according to the first embodiment.

FIG. 3 is a flowchart of a method for manufacturing an electrical wiring substrate according to the first embodiment.

FIG. 4 is a schematic plan view of a thermal print head according to a second embodiment.

FIG. 5 is a schematic cross-sectional view of the thermal print head along the sectional line V-V in FIG. 4 according to the second embodiment.

FIG. 6 is a schematic enlarged partial plan view of the thermal print head according to the second embodiment.

FIG. 7 is a flowchart of a method for manufacturing the thermal print head according to the second embodiment.

### DETAILED DESCRIPTION OF THE EMBODIMENTS

Details of examples of the embodiments of the present disclosure are given with the accompanying drawings below. Moreover, the same or equivalent parts are denoted by the same numerals or symbols in the accompanying drawings below, and related description is omitted. At least part of the configurations of the embodiments described below can be combined as desired.

### First Embodiment

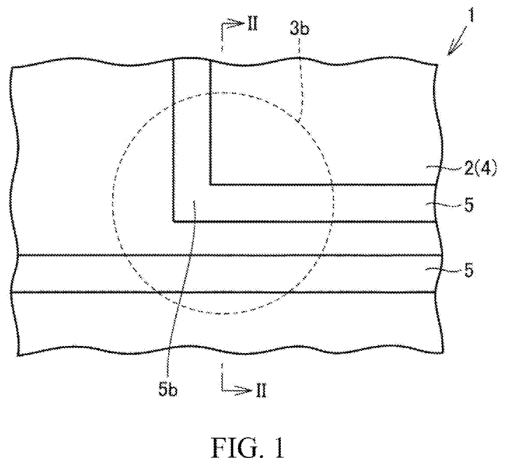

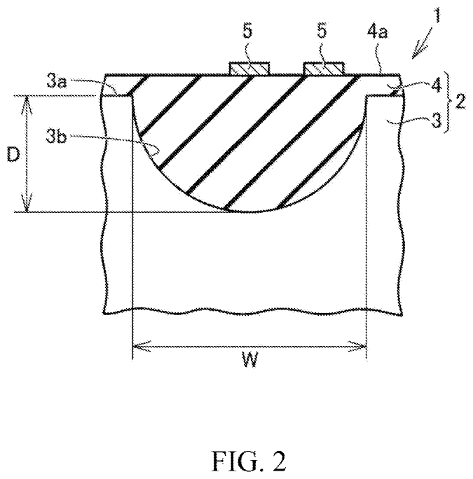

Referring to FIG. 1 and FIG. 2, an electrical wiring substrate 1 according to a first embodiment is described below. The electrical wiring substrate 1 includes an insulating substrate 2 and a wiring layer 5.

The insulating substrate 2 includes a ceramic substrate 3 and a planarization layer 4.

The ceramic substrate 3 is formed of a ceramic material such as aluminum oxide. The ceramic substrate 3 includes a main surface 3a. A recess 3b is formed on the main surface 3a. The recess 3b is, for example, formed on the main surface 3a during manufacturing of the ceramic substrate 3. A size of the recess 3b is, for example, 10 micrometers (μm) or more. The size of the recess 3b is smaller when in terms of a depth D of the recess 3b and a width W of the recess 3b.

The planarization layer 4 covers the main surface 3a of the ceramic substrate 3. The planarization layer 4 can cover a portion of the main surface 3a of the ceramic substrate 3, or can cover an entirety of the main surface 3a of the ceramic substrate 3. The planarization layer 4 includes a main surface 4a on a side opposite to the ceramic surface 3. The recess 3b of the ceramic substrate 3 is filled with the planarization layer 4. Thus, the main surface 4a of the planarization layer 4 is flatter than the main surface 3a of the ceramic substrate 3. The planarization layer 4 can also be disposed on a part of the main surface 3a of the ceramic substrate 3 where the recess 3b is not formed.

The planarization layer 4 is a ceramic layer. The ceramic layer is formed of a ceramic material such as aluminum oxide as a main component. In the present literature, the term “main component” mains that the content of ceramic in the ceramic layer is 50% or more by mass. The content of ceramic in the ceramic layer can be 70% or more by mass, or can be 80% or more by mass, or can even be 90% or more by mass.

The ceramic layer is, for example, a sintered ceramic powder layer formed by sintering a ceramic powder having a particle size less than the size of the recess 3b. A particle size of the ceramic powder is less than one-third of a size of the recess 3b. The particle size of the ceramic powder is, for example, 2 μm or less. The particle size of the ceramic powder can be, 1.5 μm or less, or 1.0 μm or less, or can even be 0.5 μm or less. The ceramic powder is, for example, high-purity aluminum oxide powder such as AKP-30, AKP-53 or AKP-700 manufactured by Sumitomo Chemical Co., Ltd. In the present literature, the particle size of the powder is a center particle size of a particle size distribution measured by a laser diffraction method using a particle size distribution measuring device MT3000 manufactured by MICROTRAC Corporation.

The wiring layer 5 disposed on the main surface 4a of the planarization layer 4. The wiring layer 5 is formed by a conductive material such as gold (Au), silver (Ag) or copper (Cu). The wiring layer 5 can include a curved portion 5b.

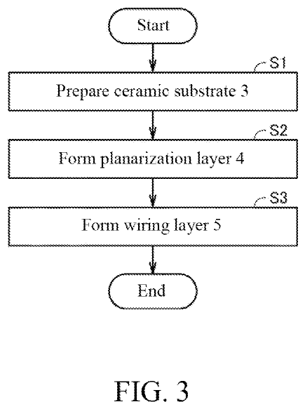

Referring to FIG. 3, an example of a method for manufacturing the electrical wiring substrate 1 of this embodiment is described below.

Referring to FIG. 3, the method for manufacturing the electrical wiring substrate 1 of this embodiment includes preparing a ceramic substrate 3 (step S1). The ceramic substrate 3 is manufactured by a generally known method. The ceramic substrate 3 includes a main surface 3a. A recess 3b is formed on the main surface 3a. A size of the recess 3b is, for example, 10 μm or more.

The method for manufacturing the electrical wiring substrate 1 of this embodiment includes forming a planarization layer 4 on the main surface 3a of the ceramic substrate 3 (step S2). The recess 3b is filled with the planarization layer 4. The planarization layer 4 can also be disposed on a part of the main surface 3a of the ceramic substrate 3 where the recess 3b is not formed. The planarization layer 4 is a ceramic layer such as a sintered ceramic powder layer in which a ceramic powder is sintered.

More specifically, a first paste is applied onto the main surface 3a of the ceramic substrate 3. The first paste is applied by, for example, using such as silk printing or by using a dispenser. The recess 3b of the ceramic substrate 3 is filled with the first paste. The first paste can also be disposed on a part of the main surface 3a of the ceramic substrate 3 where the recess 3b is not formed. The first paste includes a ceramic powder having a particle size less than the size of the recess 3b. A particle size of the ceramic powder is less than one-third of a size of the recess 3b. The particle size of the ceramic powder is, for example, 2 μm or less. Then, the first paste is sintered. The first paste becomes the planarization layer 4.

The method for manufacturing the electrical wiring substrate 1 of this embodiment includes forming a wiring layer 5 on the planarization layer 4 (step S3).

More specifically, a second paste is applied onto the planarization layer 4. The second paste is formed by a conductive material such as Au, Ag or Cu. The second paste is applied by, for example, using such as silk printing or by using a dispenser.

If necessary, the second paste is patterned. For example, the second paste is patterned by lithography. More specifically, the second paste is dried. A photoresist is applied onto the second paste. The photoresist is covered by a photomask. The photoresist is exposed by ultraviolet light through an opening of the photomask. A part of the photoresist having been deteriorated by ultraviolet light is dissolved by a developer. The photoresist is patterned. The second paste is etched by an etching agent through the patterned photoresist. The second paste is patterned. The etching agent is dissolved by a stripping liquid and thus removed.

The second paste is sintered. The second paste becomes the wiring layer 5.

Step S1 and step S2 of the method for manufacturing the electrical wiring layer 1 of this embodiment are the method for manufacturing the insulating substrate 2 of this embodiment. That is to say, the method for manufacturing the electrical wiring layer 1 of this embodiment includes the method for manufacturing the insulating substrate 2 of this embodiment.

Effects of this embodiment are described below.

The planarization layer 4 is disposed on the ceramic substrate 3. The wiring layer 5 can be formed on the main surface 4a of the planarization layer 4 flatter than the main surface 3a of the ceramic substrate 3. Thus, wire breaking of the wiring layer 5 caused by the recess 3b of the ceramic substrate 3 can be prevented. Moreover, patterning malfunction of the second paste caused by the recess 3b of the ceramic substrate 3 can be prevented. Thus, short-circuitry amidst the wiring layer 5 caused by patterning malfunction of the second paste 2 can be prevented.

The planarization layer 4 is a ceramic layer. Thus, compared to a glass layer which is a comparison example for a planarization layer, softening of the ceramic layer which is the planarization layer 4 of this embodiment during sintering of the second paste can be prevented. Strain applied upon the wiring layer 5 is reduced due to softening of the planarization layer 4. Wire breaking of the wiring layer 5 (and more particularly the curved portion 5b of the wiring layer 5) can be prevented.

The effects of the insulating substrate 2 and the electrical wiring substrate 1 as well as the manufacturing methods thereof of this embodiment are described below.

The insulating substrate 2 of this embodiment includes the ceramic substrate 3 including the main surface 3a and the planarization layer 4 covering the main surface 3a. The planarization layer 4 is a ceramic layer.

Thus, when the wiring layer 5 is formed on the planarization layer 4, softening of the planarization layer 4 is prevented. Strain applied upon the wiring layer 5 is reduced due to softening of the planarization layer 4. Wire breaking of the wiring layer 5 can be prevented.

In the insulating substrate 2 of this embodiment, the recess 3b is formed on the main surface 3a of the ceramic substrate 3. The recess 3b is filled with the planarization layer 4.

Thus, wire breaking of the wiring layer 5 caused by the recess 3b of the ceramic substrate 3 can be prevented. Moreover, when the wiring layer 5 is formed on the planarization layer 4, patterning malfunction of the wiring layer 5 caused by the recess 3b of the ceramic substrate 3 can be prevented. Short-circuitry amidst the wiring layer 5 can be prevented.

In the insulating substrate 2 of this embodiment, the ceramic layer is, for example, a sintered ceramic powder layer formed by sintering a ceramic powder having a particle size less than the size of the recess 3b.

Thus, the recess 3b of the ceramic substrate 3 is more reliably filled with the ceramic powder. Wire breaking of the wiring layer 5 caused by the recess 3b of the ceramic substrate 3 can be prevented. Moreover, when the wiring layer 5 is formed on the planarization layer 4, patterning malfunction of the wiring layer 5 caused by the recess 3b of the ceramic substrate 3 can be prevented. Short-circuitry amidst the wiring layer 5 can be prevented.

In the insulating substrate 2 of this embodiment, the particle size of the ceramic powder is one-third or less of the size of the recess 3b.

Thus, the recess 3b of the ceramic substrate 3 is more reliably filled with the ceramic powder. Wire breaking of the wiring layer 5 caused by the recess 3b of the ceramic substrate 3 can be prevented. Moreover, when the wiring layer 5 is formed on the planarization layer 4, patterning malfunction of the wiring layer 5 caused by the recess 3b of the ceramic substrate 3 can be prevented. Short-circuitry amidst the wiring layer 5 can be prevented.

In the insulating substrate 2 of this embodiment, the size of the recess 3b is, for example, 10 μm or more. The particle size of the ceramic powder is 2 μm or less.

Thus, the recess 3b of the ceramic substrate 3 is more reliably filled with the ceramic powder. Wire breaking of the wiring layer 5 caused by the recess 3b of the ceramic substrate 3 can be prevented. Moreover, when the wiring layer 5 is formed on the planarization layer 4, patterning malfunction of the wiring layer 5 caused by the recess 3b of the ceramic substrate 3 can be prevented. Short-circuitry amidst the wiring layer 5 can be prevented.

The electrical wiring substrate 1 of this embodiment includes the insulating substrate 2 of this embodiment and the wiring layer 5 disposed on the planarization layer 4.

Because the planarization layer 4 is a ceramic layer, softening of the planarization layer 4 is prevented when the wiring layer 5 is formed on the planarization layer 4. Strain applied upon the wiring layer 5 is reduced due to softening of the planarization layer 4. Wire breaking of the wiring layer 5 can be prevented.

The method for manufacturing the insulating substrate 2 of this embodiment includes preparing the ceramic substrate 3 including the main surface 3a (step S1), and forming the planarization layer 4 by applying the first paste onto the main surface 3a and sintering the first paste (step S2). The planarization layer 4 is a ceramic layer.

Thus, when the wiring layer 5 is formed on the planarization layer 4, softening of the planarization layer 4 is prevented. Strain applied upon the wiring layer 5 is reduced due to softening of the planarization layer 4. Wire breaking of the wiring layer 5 can be prevented.

In the method for manufacturing the insulating substrate 2 of this embodiment, the recess 3b is formed on the main surface 3a. The recess 3b is filled with the planarization layer 4.

Thus, wire breaking of the wiring layer 5 caused by the recess 3b of the ceramic substrate 3 can be prevented. Moreover, when the wiring layer 5 is formed on the planarization layer 4, patterning malfunction of the wiring layer 5 caused by the recess 3b of the ceramic substrate 3 can be prevented. Short-circuitry amidst the wiring layer 5 can be prevented.

In the method for manufacturing the insulating substrate 2 of this embodiment, the first paste includes a ceramic powder having a particle size less than the size of the recess 3b. The planarization layer 4 is a sintered ceramic powder layer in which a ceramic powder is sintered.

Thus, the recess 3b of the ceramic substrate 3 is more reliably filled with the ceramic powder. Wire breaking of the wiring layer 5 caused by the recess 3b of the ceramic substrate 3 can be prevented. Moreover, when the wiring layer 5 is formed on the planarization layer 4, patterning malfunction of the wiring layer 5 caused by the recess 3b of the ceramic substrate 3 can be prevented. Short-circuitry amidst the wiring layer 5 can be prevented.

In the method for manufacturing the insulating substrate 2 of this embodiment, the particle size of the ceramic powder is one-third or less of the size of the recess 3b.

Thus, the recess 3b of the ceramic substrate 3 is more reliably filled with the ceramic powder. Wire breaking of the wiring layer 5 caused by the recess 3b of the ceramic substrate 3 can be prevented. Moreover, when the wiring layer 5 is formed on the planarization layer 4, patterning malfunction of the wiring layer 5 caused by the recess 3b of the ceramic substrate 3 can be prevented. Short-circuitry amidst the wiring layer 5 can be prevented.

In the method for manufacturing the insulating substrate 2 of this embodiment, the size of the recess 3b is 10 μm or more. The particle size of the ceramic powder is 2 μm or less.

Thus, the recess 3b of the ceramic substrate 3 is more reliably filled with the ceramic powder. Wire breaking of the wiring layer 5 caused by the recess 3b of the ceramic substrate 3 can be prevented. Moreover, when the wiring layer 5 is formed on the planarization layer 4, patterning malfunction of the wiring layer 5 caused by the recess 3b of the ceramic substrate 3 can be prevented. Short-circuitry amidst the wiring layer 5 can be prevented.

The method for manufacturing the electrical wiring substrate 1 of this embodiment includes manufacturing the insulating substrate 2 by the method for manufacturing the insulating substrate 2 of this embodiment (step S1 and step S2), and forming the wiring layer 5 by applying a second paste onto the planarization layer 4 and sintering the second paste (step S3).

Because the planarization layer 4 is a ceramic layer, softening of the planarization layer 4 is prevented when the wiring layer 5 is formed on the planarization layer 4. Strain applied upon the wiring layer 5 is reduced due to softening of the planarization layer 4. Wire breaking of the wiring layer 5 can be prevented.

### Second Embodiment

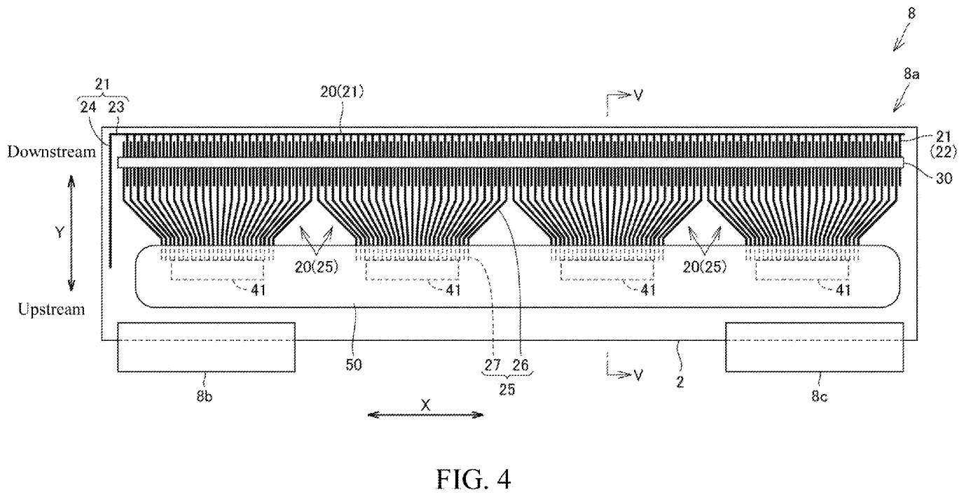

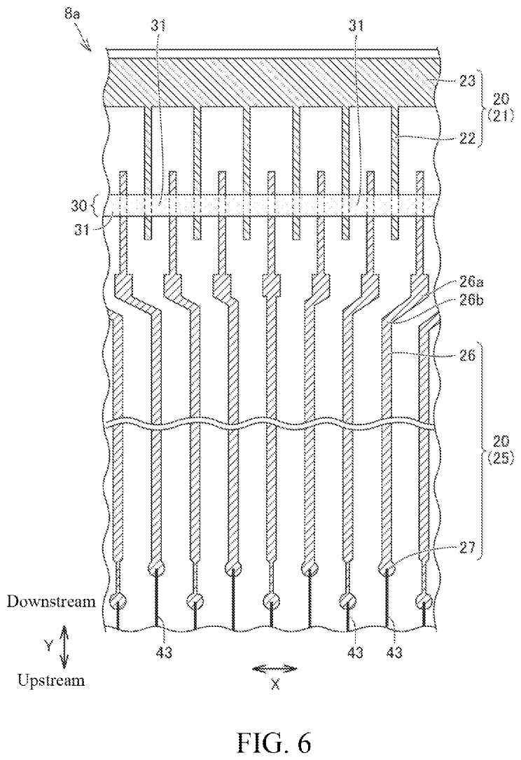

Referring to FIG. 4 to FIG. 6, a thermal print head 8 according to the second embodiment is described below. The thermal print head 8 is mounted on a thermal printer (not shown).

Referring to FIG. 4, the thermal print head 8 includes a head body 8a and connectors 8b and 8c.

The head body 8a has, for example, a rectangular shape. In a plan view of the thermal print head 8 (to be referred to as “plan view” for short below), a long side direction of the head body 8a is a main scan direction X, a short side direction of the head body 8a is referred to as a secondary scan direction Y, and a thickness direction of the ceramic substrate 3 is referred to as a plate thickness direction Z. The plate thickness direction Z is a direction perpendicular to the main scan direction X and the secondary scan direction Y. In the plan view, the secondary scan direction Y is a conveying direction of a printing medium (for example, thermal recording paper).

The connectors 8b and 8c are connected to connectors (not shown) on a side of a thermal printer (not shown) when the thermal print head 8 is assembled to the thermal printer. The connectors 8b and 8c are connected to an upstream end of the head body 8a in the secondary scan direction Y.

Referring to FIG. 4 to FIG. 6, the head body 8a includes an insulating substrate 2, a glaze 13, a wiring layer 20, pads 28 and 29, a heat resistor 30, a protection layer 35, a support glass layer 38, a driver integrated circuit (IC) 41, conductive wires 43 and 44, and a sealing component 50.

The insulating layer 2 of this embodiment is the same as the insulating substrate 2 of the first embodiment. More specifically, the insulating substrate 2 includes the ceramic substrate 3 and a planarization layer 10. The ceramic substrate 3 of this embodiment is the same as the ceramic substrate 3 of the first embodiment.

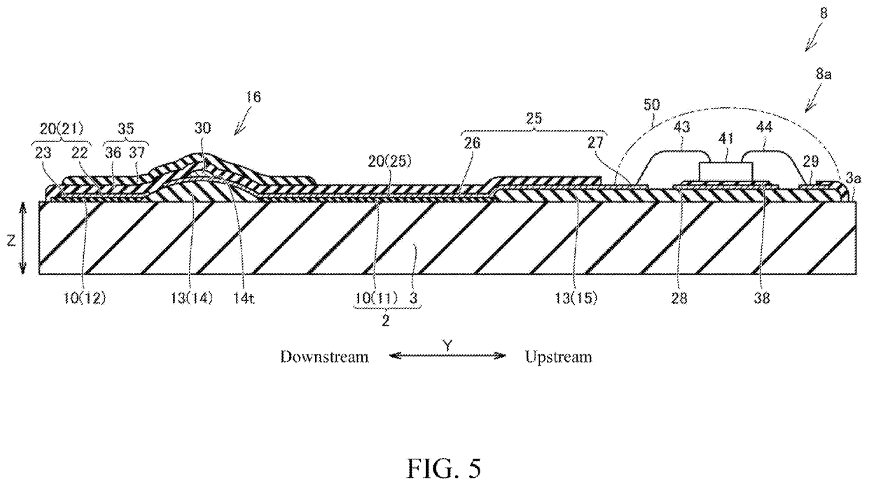

Referring to FIG. 5, the glaze 13 is disposed on the main surface 3a of the ceramic substrate 3. The glaze 13 is formed of, for example, a glass material such as amorphous glass. The glaze 13 includes a heat glaze 14 and a chip bonding glaze 15.

The heat glaze 14 is a heat storage layer. The heat glaze 14 extends in the main scan direction X and has a strip shape in the plan view of the main surface 3a of the ceramic substrate 3. In this embodiment, the heat glaze 14 is a so-called partial glaze. That is to say, in a cross section including the secondary scan direction Y and the plate thickness direction Z, the heat glaze 14 protrudes from a portion of the main surface 3a of the ceramic substrate 3. The heat glaze 14 is provided to press the heat resistor 30 onto the printing medium (for example, thermal recording paper). A thickness of the heat glaze 14 is, for example, between about 18 μm and about 50 μm.

The chip bonding glaze 15 is disposed to be separated from the heat glaze 14 toward the upstream in the secondary scan direction Y. The chip bonding glaze 15 extends in the main scan direction X and has a strip shape in the plan view of the main surface 3a of the ceramic substrate 3. The chip bonding glaze 15 supports a portion of the wiring layer 20 and the driver IC 41. A thickness of the chip bonding glaze 15 is, for example, between about 30 μm and about 50 μm. Moreover, the chip bonding glaze 15 can be omitted.

Referring to FIG. 5, the planarization layer 10 of this embodiment is the same as the planarization layer 4 of the first embodiment. More specifically, the planarization layer 10 is a ceramic layer. A thickness of the planarization layer 10 is greater than a thickness of the glaze 13. The thickness of the planarization layer 10 is, for example, about 2 μm.

The planarization layer 10 includes a central portion 11 and a peripheral portion 12. The central portion 11 covers a part located between the heat glaze 14 and the chip bonding glaze 15 on the main surface 3a of the ceramic substrate 3. The peripheral portion 12 covers a part located on a downstream in the secondary scan direction Y with respect to the heat glaze 14 on the main surface 3a of the ceramic substrate 3. The planarization layer 10 is in contact with the glaze 13. More specifically, the central portion 11 is contact with the heat glaze 14 and the chip bonding glaze 15. The peripheral portion 12 is in contact with the heat glaze 14.

Referring to FIG. 4 to FIG. 6, the wiring layer 20 disposed on the glaze 13 and the planarization layer 10. The wiring layer 20 forms a conductive path for energizing the heat resistor 30. The wiring layer 20 of this embodiment is formed of the same material and by the same method as the wiring layer 5 of the first embodiment. A thickness of the wiring layer 20 is not specifically defined, and is, for example, between about 0.6 μm and about 1.2 μm. The wiring layer 20 includes a common wiring 21 and a plurality of independent wirings 25.

The common wiring 21 is disposed on the heat glaze 14 and the peripheral portion 12 of the planarization layer 10. The common wiring 21 includes a plurality of first strip portions 22, a connecting portion 23 and an avoidance portion 24.

The plurality of first strip portions 22 are disposed on the heat glaze 14 and the peripheral portion 12 of the planarization layer 10. The plurality of first strip portions 22 individually extend in the secondary scan direction Y. The plurality of first strip portions 22 are equidistantly arranged in the main scanning direction X. The connecting portion 23 is disposed on the peripheral portion 12 of the planarization layer 10. The connecting portion 23 extends in the main scanning direction X. The connecting portion 23 is connected to the plurality of first strip portions 22. The avoidance portion 24 extends from one end of the connecting portion 23 in the main scan direction X toward the upstream in the secondary scan direction Y to avoid the plurality of independent wirings 25.

Each of the plurality of independent wirings 25 partially energizes the heat resistor 30. Each of the plurality of independent wirings 25 extends from the heat glaze 14 to the chip bonding glaze 15 in the secondary scan direction Y. Each of the plurality of independent wirings 25 includes a second strip portion 26 and a bonding portion 27.

The second strip portion 26 extends from the heat glaze 14 to the chip bonding glaze 15 in the secondary scan direction Y. The second strip portion 26 includes curved portions 26a and 26b. The plurality of second strip portions 26 are equidistantly arranged in the main scanning direction X. The second strip portion 26 is disposed between a pair of adjacent first strip portions 22 in the main scan direction X on the heat glaze 14. The first strip portion 22 and the second strip portion 26 are arranged alternately in the main scan direction X. An upstream end of each of the plurality of independent wirings 25 in the secondary scan direction Y is connected to the bonding portion 27. A width of the bonding portion 27 is greater than a width of the second strip portion 26.

Referring to FIG. 5, the pads 28 and 29 are formed of the same material as the wiring layer 20. The pads 28 and 29 are disposed on the chip bonding glaze 15. In the secondary scan direction Y, the pad 28 is disposed between the plurality of independent wirings 25 and the pad 29. In the secondary scan direction Y, the pad 28 is disposed to be separated from the plurality of the independent wirings 25 toward the upstream of the secondary scan direction Y. The pad 29 is disposed to be separated from the pad 28 toward the upstream in the secondary scan direction Y.

Referring to FIG. 4 to FIG. 6, the heat resistor 30 placed on the heat glaze 14. More specifically, the heat resistor 30 placed on a top of the heat glaze 14. The top of the heat glaze 14 is a part having a largest height from the main surface 3a of the ceramic substrate 3 to a surface of the heat glaze 14 in the plate thickness direction Z. The top of the heat glaze 14 is, for example, located at a center of the heat glaze 14 in the secondary scan direction Y. The heat resistor 30 extends in the main scan direction X and has a strip shape in the plan view. In a cross section including the secondary scan direction Y and the plate thickness direction Z, the heat resistor 30 protrudes toward a side opposite to the ceramic substrate 3 with respect to the heat glaze 14. A thickness of the heat resistor 30 is, for example, between about 6 μm and about 10 μm.

The heat resistor 30 is connected to the wiring layer 20. More specifically, the heat resistor 30 is connected to the plurality of first strip portions 22 of the common wiring 21 and the plurality of second strip portions 26 of the plurality of independent wirings 25. In the plan view, the heat resistor 30 is configured to intersect the plurality of first strip portions 22 and the plurality of second strip portions 26. The heat resistor 30 is formed to cross the plurality of first strip portions 22 and the plurality of second strip portions 26. In the heat resistor 30, a part sandwiched by each first strip portion 22 and each second strip portion 26 in the main scan direction X is a heat generating portion 31. The heat generating portion 31 is a part which is partially energized by the heat resistor 30 and thus generates heat. Printing is performed on a printing medium (for example, thermal recording paper) with the heating of the heat generating portion 31.

Referring to FIG. 5, the protection layer 35 at least protects the heat resistor 30. The protection layer 35 can further protect the common wiring 21 and the plurality of independent wirings 25. The protection layer 35 includes a first protection layer 36 and a second protection layer 37.

The first protection layer 36 at least covers the heat generating portion 31 of the heat resistor 30. The first protection layer 36 can cover an entirety of the heat resistor 30. The first protection layer 36 can further cover the plurality of first strip portions 22 and the plurality of second strip portions 26. The first protection layer 36 can also further cover the central portion 11 and the peripheral portion 12 of the planarization layer 10, and a portion of the chip bonding glaze 15. The first protection layer 36 is formed of, for example, amorphous glass. A thickness of the first protection layer 36 is not specifically defined, and is, for example, between about 6 μm and about 8 μm.

The second protection layer 37 is formed over the first protection layer 36. The second protection layer 37 is formed in a region in which a printing medium (for example, thermal recording paper) may come into contact with the thermal print head 8 while the printing medium is conveyed. In the plan view, a length of the second protection layer 37 in the secondary scan direction Y is shorter than a length of the first protection layer 36 in the secondary scan direction Y. The second protection layer 37 is, for example, a coating film containing silicon carbide (SiC) or titanium (Ti). A thickness of the second protection layer 37 is less than the thickness of the first protection layer 36. The thickness of the second protection layer 37 is not specifically defined, and is, for example, between about 2 μm and about 4 μm.

Referring to FIG. 5, the support glass layer 38 is disposed on the pad 28. The support glass layer 38 is formed of, for example, amorphous glass.

Referring to FIG. 4 and FIG. 5, the driver IC 41 selectively energizes the plurality of independent wirings 25. In this embodiment, a plurality of driver ICs 41 are arranged to be separated in the main scan direction X. The driver IC 41 is disposed on the chip bonding glaze 15. More specifically, the driver IC 41 is disposed on the support glass layer 38.

Referring to FIG. 5, the conductive wire 43 is bonded to the bonding portions 27 of the plurality of independent wirings 25 and the driver IC 41. The conductive wire 43 electrically connects the plurality of independent wirings 25 with the driver IC 41. The conductive wire 44 is bonded to the pad 29 and the driver IC 41. The conductive wire 44 electrically connects the pad 29 with the driver IC 41.

Referring to FIG. 4 and FIG. 5, the sealing component 50 seals the driver IC 41. The sealing component 50 is electrically insulative. The sealing component 50 is formed of, for example, an insulative resin such as epoxy.

As shown in FIG. 5, the thermal print head 8 includes a protrusion 16 formed on the main surface 3a of the ceramic substrate 3. The protrusion 16 includes the glaze 13 (the heat glaze 14), the wiring layer 20, the heat resistor 30 and the protection layer 35. In the protrusion 16, the glaze 13 (the heat glaze 14), the wiring layer 20, the heat resistor 30 and the protection layer 35 are sequentially laminated on the main surface 3a in a normal direction of the main surface 3a (the Z direction).

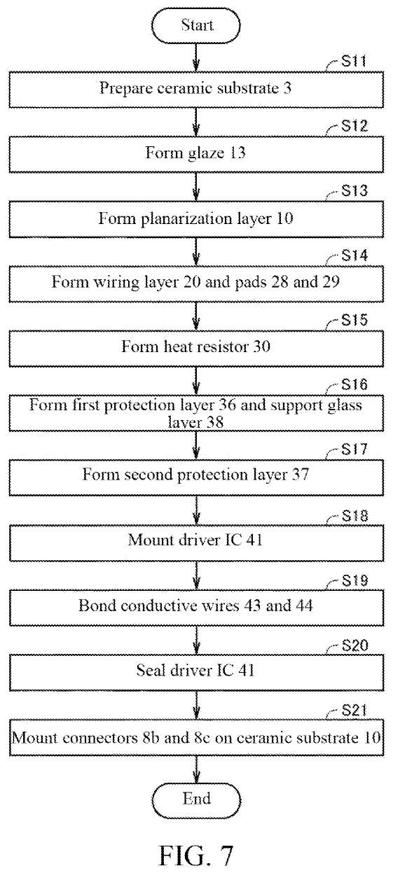

Referring to FIG. 7, the method for manufacturing the thermal print head 8 of this embodiment is described below.

The method for manufacturing the thermal print head 8 of this embodiment includes preparing a ceramic substrate 3 (step S11). Step S11 of this embodiment is the same as step S1 of the first embodiment. More specifically, a recess 3b (referring to FIG. 1 and FIG. 2) is formed on a main surface 3a of the ceramic substrate 3.

The method for manufacturing the thermal print head 8 of this embodiment includes forming a glaze 13 on the main surface 3a of the ceramic substrate 3 (step S12). More specifically, a first glass paste is applied onto the main surface 3a of the ceramic substrate 3. The first glass paste is applied by, for example, using such as silk printing or by using a dispenser. Then, the first glass paste is sintered. The first glass paste becomes the glaze 13.

The method for manufacturing the thermal print head 8 of this embodiment includes forming a planarization layer 10 at a part exposed from the glaze 13 on the main surface 3a of the ceramic substrate 3 (step S13). Step S13 of this embodiment is the same as step S2 of the first embodiment.

More specifically, a first paste is applied to the part exposed from the glaze 13 on the main surface 3a of the ceramic substrate 3. The first paste is applied by, for example, using such as silk printing or by using a dispenser. The first paste of this embodiment is the same as the first paste of the first embodiment. More specifically, the first paste includes a ceramic powder having a particle size less than the size of the recess 3b (referring to FIG. 1 and FIG. 2). The recess 3b of the ceramic substrate 3 is filled with the first paste. The first paste is in contact with the glaze 13. More specifically, the first paste is contact with the heat glaze 14 and the chip bonding glaze 15. Then, the first paste is sintered. The first paste becomes the planarization layer 10. A sintering temperature of the first paste is lower than a sintering temperature of the first glass paste.

The method for manufacturing the thermal print head 8 of this embodiment includes forming a wiring layer 20 and pads 28 and 29 (step S14). Step S14 of this embodiment is the same as step S3 of the first embodiment.

More specifically, a second paste is applied onto the glaze 13 and the planarization layer 10. The applying process of the second paste of this embodiment is the same as the applying process of the second paste of the first embodiment. For example, the second paste is formed by a conductive material such as Au, Ag or Cu. The second paste is applied by, for example, using such as silk printing or by using a dispenser.

If necessary, the second paste is patterned. The patterning process of the second paste of this embodiment is the same as the patterning process of the second paste of the first embodiment. Then, the second paste is sintered. The second paste becomes the wiring layer 20 and pads 28 and 29. The sintering process of the second paste of this embodiment is the same as the sintering process of the second paste of the first embodiment. A sintering temperature of the second paste is lower than the sintering temperature of the first glass paste.

The method for manufacturing the thermal print head 8 of this embodiment includes forming a heat resistor 30 (step S15). More specifically, a resistor paste is applied onto the heat glaze 14 and the wiring layer 20. The resistor paste includes, for example, a conductive material such as ruthenium oxide, tantalum nitride, tantalum or silver vanadium, and glass. Then, the resistor paste is sintered. The resistor paste becomes the heat resistor 30. A sintering temperature of the resistor paste is lower than the sintering temperature of the first glass paste.

The method for manufacturing the thermal print head 8 of this embodiment includes forming a first protection layer 36 and a support glass layer 38 (step S16). More specifically, a second glass paste is applied onto the glaze 13, the planarization layer 10, the wiring layer 20, the pad 28 and the heat resistor 30. The second glass paste is applied by, for example, using such as silk printing or by using a dispenser. Then, the second glass paste is sintered. The second glass paste becomes the first protection layer 36 and the support glass layer 38. A sintering temperature of the second glass paste is lower than the sintering temperature of the first glass paste.

The method for manufacturing the thermal print head 8 of this embodiment includes forming a second protection layer 37 over the first protection layer 36 (step S17). The second protection layer 37 is formed by, for example, sputtering.

The method for manufacturing the thermal print head 8 of this embodiment includes mounting a driver IC 41 on the support glass layer 38 (step S18). The driver IC 41 is fixed at the support glass layer 38 by using a bonding component (not shown) such as a resin adhesive or a solder material.

The method for manufacturing the thermal print head 8 of this embodiment includes bonding conductive wires 43 and 44 (step S19). The conductive wire 43 is bonded to the driver IC 41 and a bonding portion 27 of an independent wire 25. The conductive wire 44 is bonded to the driver IC 41 and the pad 29.

The method for manufacturing the thermal print head 8 of this embodiment includes sealing the driver IC 41 (step S20). More specifically, a sealing resin material is pour onto the driver IC 41. The sealing resin material is hardened to become the sealing component 50.

The method for manufacturing the thermal print head 8 of this embodiment includes mounting connectors 8b and 8c on the ceramic substrate 3 (step S21). The connectors 8b and 8c are connected to an upstream end of the ceramic substrate 3 in the secondary scan direction Y. As such, the thermal print head 8 is obtained.

Step S11, step S13 and step S14 of this embodiment respectively correspond to step S1, step S2 and step S3 of the first embodiment. That is to say, the method for manufacturing the thermal print head 8 of this embodiment includes the method for manufacturing the electrical wiring substrate 1 and the method for manufacturing the insulating substrate 2 of this embodiment of the first embodiment.

In addition to the effects of the first embodiment, the thermal print head 8 of this embodiment further achieve the additional effects below. Compared to a thermal print head of a comparison example, the additional effects achieved the thermal print head 8 of this embodiment are described below. Although the thermal print head of the comparison example has a same configuration as the thermal print head 8 of this embodiment, in the thermal print head of the comparison example, the planarization layer 10 is a glass layer having a softening point lower than that of the glaze 13.

In the thermal print head of the comparison example, the reason why the softening point of the planarization layer 10 which is a glass layer is lower than the softening point of the glaze 13 is as below.

If the softening point of the planarization layer 10 which is a glass layer is higher than the softening point of the glaze 13, the glaze 13 softens and thus the shape of the glaze 13 collapses during the sintering of the glass paste for the planarization layer 10. More particularly, in case where the planarization layer 10 (or the glass paste for the planarization layer 10) comes into contact with the glaze 13, the glaze 13 becomes an integral with the planarization layer 10 during the sintering of the glass paste for the planarization layer 10, so the shape of the glaze 13 significantly collapses. As a result, a height of the heat glaze 14 is reduced. In the thermal printing head, the protrusion 16 which includes the glaze 13 (the heat glaze 14), the wiring layer 20, the heat resistor 30 and the protection layer 35 cannot fully contact a printing medium (for example, thermal recording paper), so printing quality of the thermal print head is degraded. With respect to the above, in the thermal print head of the comparison example, the softening point of the planarization layer 10 which is a glass layer is lower than the softening point of the glaze 13. Thus, collapsing of the shape of the glaze 13 during the sintering of the glass paste for the planarization layer 10 is prevented. Degradation of the printing quality of the thermal print head of the comparison example can then be prevented.

However, if the softening point of the planarization layer 10 which is a glass layer is lower than the softening point of the glaze 13 as the thermal print head of the comparison example, the planarization layer 10 softens during the sintering of the second paste (the paste for the wiring layer 20). Since softening of the planarization layer 20 applies strain on a part of the wiring layer 20 located on the planarization layer 10, the part of the wiring layer 20 sometimes encounters wire breaking.

In the thermal print head 8 of this embodiment, the planarization layer 10 is a ceramic layer. Thus, softening of the planarization layer 10 during the sintering of the second paste (the paste for the wiring layer 20) is prevented. Strain applied upon the wiring layer 20 is reduced while the wiring layer 20 is formed on the planarization layer 10. Wire breaking of the wiring layer 20 (and more particularly the curved portion 26a and 26b of the wiring layer 20) can be prevented.

Moreover, the sintering temperature of the first paste (the paste for the planarization layer 10) can be made to be lower than the sintering temperature of the first glass paste (the paste for the glaze 13). Thus, even if the planarization layer 10 (or the first paste) comes into contact with the glaze 13, the shape of the glaze 13 can still be maintained during sintering of the first paste. Thus, in the thermal printing head 8, the protrusion 16 which includes the glaze 13 (the heat glaze 14), the wiring layer 20, the heat resistor 30 and the protection layer 35 is able to fully contact a printing medium (for example, thermal recording paper). The printing quality of the thermal print head 8 can be improved.

In addition to the effects of the electrical wiring substrate 1 and the manufacturing method thereof of the first embodiment, the thermal print head 8 and the manufacturing method thereof of this embodiment further achieves the following effects.

The thermal print head 8 of this embodiment includes the insulating substrate 2, the glaze 13, the wiring layer 20 and the heat resistor 30. The glaze 13 is disposed on the ceramic substrate 3. The wiring layer 20 disposed on the glaze 13 and the planarization layer 10. The heat resistor 30 is placed on the glaze 13, and is connected to the wiring layer 20.

Because the planarization layer 10 is a ceramic layer, softening of the planarization layer 10 is prevented when the wiring layer 20 is formed on the planarization layer 10. Strain applied upon the wiring layer 20 is reduced due to softening of the planarization layer 10. Wire breaking of the wiring layer 20 can be prevented. Moreover, the shape of the glaze 13 can be maintained while the planarization layer 10 is formed. Thus, in the thermal printing head 8, the protrusion 16 which includes the glaze 13, the wiring layer 20, the heat resistor 30 and the protection layer 35 is able to fully contact a printing medium (for example, thermal recording paper). The printing quality of the thermal print head 8 can be improved.

The method for manufacturing the thermal print head 8 of this embodiment includes preparing the insulating substrate 2 by the method for manufacturing the insulating substrate 2 of this embodiment (step S11 and step S13), forming the glaze 13 by applying the glass paste (the first glass paste) onto the ceramic substrate 3 and sintering the glass paste (step S12), forming the wiring layer 20 applying the second paste including a conductive material onto the glaze 13 and the planarization layer 10 (step 14), and forming the heat resistor 30 by applying the resistor paste onto the glaze 13 and the wiring layer 20 and sintering the resistor paste (step S15). The sintering temperature of the first paste is lower than the sintering temperature of the glass paste (the first glass paste).

Because the planarization layer 10 is a ceramic layer, softening of the planarization layer 10 is prevented when the wiring layer 20 is formed on the planarization layer 10. Strain applied upon the wiring layer 20 is reduced due to softening of the planarization layer 10. Wire breaking of the wiring layer 20 can be prevented. Moreover, the shape of the glaze 13 can be maintained while the planarization layer 10 is formed. Thus, in the thermal printing head 8, the protrusion 16 which includes the glaze 13, the wiring layer 20, the heat resistor 30 and the protection layer 35 is able to fully contact a printing medium (for example, thermal recording paper). The printing quality of the thermal print head 8 can be improved.

The various forms of the present disclosure are described in summary below.

### Note 1

An insulating substrate, comprising:
a ceramic substrate, including a main surface; and
a planarization layer, covering the main surface, wherein the planarization layer is a ceramic layer.

### Note 2

The insulating substrate according to note 1, wherein a recess is formed on the main surface, and the recess is filled with the planarization layer.

### Note 3

The insulating substrate according to note 2, wherein the ceramic layer is a sintered ceramic powder layer formed by sintering a ceramic powder having a particle size less than a size of the recess.

### Note 4

The insulating substrate according to note 3, wherein the particle size of the ceramic powder is less than one-third of the size of the recess.

### Note 5

The insulating substrate according to note 3 or 4, wherein the size of the recess is greater than 10 μm, and the particle size of the ceramic powder is less than 2 μm.

### Note 6

An electrical wiring substrate, comprising:
the insulating substrate of any one of notes 1 to 5; and
a wiring layer, disposed on the planarization layer.

### Note 7

A thermal print head, comprising:

the insulating substrate of any one of notes 1 to 5;
a glaze, disposed on the ceramic substrate;
a wiring layer, disposed on the glaze and the planarization layer; and
a heat resistor, placed on the glaze and connected to the wiring layer.

### Note 8

A method for manufacturing an insulating substrate, comprising:
preparing a ceramic substrate including a main surface; and
forming a planarization layer by applying a first paste onto the main surface and sintering the first paste, wherein the planarization layer is a ceramic layer.

### Note 9

The method for manufacturing an insulating substrate according to note 8, wherein a recess is formed on the main surface, and the recess is filled with the planarization layer.

### Note 10

The method for manufacturing an insulating substrate according to note 9, wherein the first paste includes a ceramic powder having a particle size less than the size of the recess, and the planarization layer is a sintered ceramic powder layer in which the ceramic powder is sintered.

### Note 11

The method for manufacturing an insulating substrate according to note 10, wherein the particle size of the ceramic powder is less than one-third of the size of the recess.

### Note 12

The method for manufacturing an insulating substrate according to note 10 or 11, wherein the size of the recess is greater than 10 μm, and the particle size of the ceramic powder is less than 2 μm.

### Note 13

A method for manufacturing an electrical wiring substrate, comprising:
the method for manufacturing the insulating substrate according to any one of notes 8 to 12; and
forming a wiring layer by applying a second paste onto the planarization layer and sintering the second paste.

### Note 14

A method for manufacturing a thermal print head, comprising:
the method for manufacturing the insulating substrate according to any one of notes 8 to 12;
forming a glaze by applying a glass paste onto the ceramic substrate and sintering the glass paste;
forming a wiring layer by applying a second paste containing a conductive material onto the glaze and the planarization layer and sintering the second paste; and
forming a heat resistor by applying a resistor paste onto the glaze and the wiring layer and sintering the resistor paste, wherein a sintering temperature of the first paste is lower than a sintering temperature of the glass paste.

It should be understood that all aspects of the first and second embodiments of the present disclosure are exemplary rather than restrictive. The scope of the present disclosure is described and represented by way of the claims but not the description above, and is intended to cover all equivalent meanings and variations made within the scope accorded with the claims.

1. An insulating substrate, comprising:
a ceramic substrate, including a main surface; and
a planarization layer, covering the main surface, wherein
the planarization layer is a ceramic layer.

2. The insulating substrate of claim 1, wherein
a recess is formed on the main surface, and
the recess is filled with the planarization layer.

3. The insulating substrate of claim 2, wherein the ceramic layer is a sintered ceramic powder layer formed by sintering a ceramic powder having a particle size less than a size of the recess.

4. The insulating substrate of claim 3, wherein the particle size of the ceramic powder is less than one-third of the size of the recess.

5. The insulating substrate of claim 3, wherein the size of the recess is greater than 10 μm, and the particle size of the ceramic powder is less than 2 μm.

6. An electrical wiring substrate, comprising:
the insulating substrate of claim 1; and
a wiring layer, disposed on the planarization layer.

7. A thermal print head, comprising:
the insulating substrate of claim 1;
a glaze, disposed on the ceramic substrate;
a wiring layer, disposed on the glaze and the planarization layer; and
a heat resistor, placed on the glaze and connected to the wiring layer.

8. A method for manufacturing an insulating substrate, comprising:
preparing a ceramic substrate including a main surface; and
forming a planarization layer by applying a first paste onto the main surface and sintering the first paste, wherein
the planarization layer is a ceramic layer.

9. The method of claim 8, wherein
a recess is formed on the main surface, and
the recess is filled with the planarization layer.

10. The method of claim 9, wherein
the first paste includes ceramic powder having a particle size less than the size of the recess, and
the planarization layer is a sintered ceramic powder layer in which the ceramic powder is sintered.

11. The method of claim 10, wherein the particle size of the ceramic powder is less than one-third of the size of the recess.

12. The method of claim 10, wherein the size of the recess is greater than 10 μm, and the particle size of the ceramic powder is less than 2 μm.

13. A method for manufacturing an electrical wiring substrate, comprising:
the method for manufacturing the insulating substrate according to claim 8; and
forming a wiring layer by applying a second paste onto the planarization layer and sintering the second paste.

14. A method for manufacturing a thermal print head, comprising:
the method for manufacturing the insulating substrate according to claim 8;
forming a glaze by applying a glass paste onto the ceramic substrate and sintering the glass paste;
forming a wiring layer by applying a second paste containing a conductive material onto the glaze and the planarization layer and sintering the second paste; and
forming a heat resistor by applying a resistor paste onto the glaze and the wiring layer and sintering the resistor paste, wherein
a sintering temperature of the first paste is lower than a sintering temperature of the glass paste.
